(19) United States
(12) Patent Application Publication
(10) Pub. No.: US 2026/0362980 A1
(43) Pub. Date: Nov. 12, 2026

(54) WITHIN-SUBSTRATE STRESS CONTROL OF PIEZOELECTRIC FILMS USING DYNAMIC BIAS DURING PIEZOELECTRIC DEVICE FABRICATION

(71) Applicant: Applied Materials, Inc., Santa Clara, CA (US)

(72) Inventors: Bharatwaj RAMAKRISHNAN, Sunnyvale, CA (US); Vijay Bhan SHARMA, Mumbai (IN)

(21) Appl. No.: 19/124,950

(22) PCT Filed: Oct. 27, 2023
(86) PCT No.: PCT/US2023/036114

§ 371 Date: Apr. 28, 2025

(30) Foreign Application Priority Data
Oct. 31, 2022 (IN) 202241061816

(51) Int. Cl. H10N 30/06; H10N 30/00; H10N 30/076; H10N 30/853; H10N 30/87

(52) U.S. Cl. CPC H10N 30/06; H10N 30/076; H10N 30/704; H10N 30/8542; H10N 30/8554; H10N 30/878

(57) ABSTRACT

Examples disclosed herein relate to piezoelectric devices and methods of patterning piezoelectric layers for piezoelectric device fabrication. The method includes disposing a bottom electrode layer over a substrate, disposing a piezoelectric layer over the bottom electrode layer on a horizontal plane, varying an electrical bias to the pedestal during deposition of the piezoelectric layer, and forming a top electrode layer with a top electrode pattern over the piezoelectric layer. The substrate is supported by a pedestal. A piezoelectric device includes a substrate, a bottom electrode layer formed over the substrate, a piezoelectric layer formed over the bottom electrode layer on a horizontal plane, and a top electrode layer formed on the piezoelectric layer. Within the piezoelectric layer an average stress of a plurality of stresses along the horizontal plane is about 50 MPa to about 300 MPa.

### BACKGROUND

### Field

Embodiments of the present disclosure generally relate to piezoelectric devices. More specifically, embodiments disclosed herein relate to piezoelectric devices and methods of forming piezoelectric layers for piezoelectric device fabrication.

### Description of the Related Art

Piezoelectric materials, which are materials that accumulate electric charge upon application of mechanical stress, are frequently used in sensors and transducers for piezoelectric devices such as gyro-sensors, ink-jet printer heads, ultrasound technology, and other microelectromechanical systems (MEMS) devices, including acoustic resonators for mobile phones and other wireless electronics. Fabricating the piezoelectric devices can be difficult due the brittle properties of the piezoelectric material and the within-substrate stress. Stress ranges within the substrate can be as high as 100 MPa, due to the thickness of the film, stress gradients across the film in the vertical direction, and other factors. These high stress ranges affect the performance and yield of the piezoelectric devices.

Accordingly, what is needed in the art are improved fabrication methods of piezoelectric materials.

### SUMMARY

In one embodiment, a method of forming a piezoelectric device is disclosed. The method of forming a piezoelectric device includes disposing a bottom electrode layer over a substrate, the substrate being supported by a pedestal. A piezoelectric layer is disposed over the bottom electrode layer along a horizontal plane. An electrical bias is varied to the pedestal during deposition of the piezoelectric layer. A top electrode layer is formed with a top electrode pattern over the piezoelectric layer.

In another embodiment, a piezoelectric device is disclosed. The device includes a substrate, a bottom electrode layer formed over the substrate, a piezoelectric layer formed over the bottom electrode layer along a horizontal plane, and a top electrode layer formed over the piezoelectric layer. Within the piezoelectric layer an average stress of a plurality of stresses along the horizontal plane is about 50 MPa to about 300 MPa.

In yet another embodiment, a controller of a process system is disclosed. The controller includes storing instructions that, when executed by a processor, causes the system to process a substrate within a processing chamber by disposing a bottom electrode layer over a substrate. The substrate is supported by a pedestal. A piezoelectric layer is disposed over the bottom electrode layer. An electrical bias is varied to the pedestal during deposition of the piezoelectric layer. A top electrode layer is formed with a top electrode pattern over the piezoelectric layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic, top view of a piezoelectric device, according to embodiments described herein

FIG. 2 is a schematic cross-sectional view of piezoelectric devices according to embodiments described herein.

FIG. 3 is a flow diagram of a method of forming a piezoelectric device, according to embodiments described herein.

FIGS. 4A-4C are schematic, side views of a substrate during the method of FIG. 3 of forming a piezoelectric device, according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to piezoelectric devices. More specifically, embodiments disclosed herein relate to piezoelectric devices and methods of fabricating piezoelectric layers for piezoelectric device fabrication.

Patterning piezoelectric material in piezoelectric devices can be challenging due to the brittle and hard characteristics of the piezoelectric material. For piezoelectric devices, it is beneficial to pattern the piezoelectric material while controlling the stress range across the substrate. An improvement in patterning the piezoelectric material can be achieved through the methods disclosed herein. The methods disclosed herein enable patterning of the piezoelectric material with increased throughput.

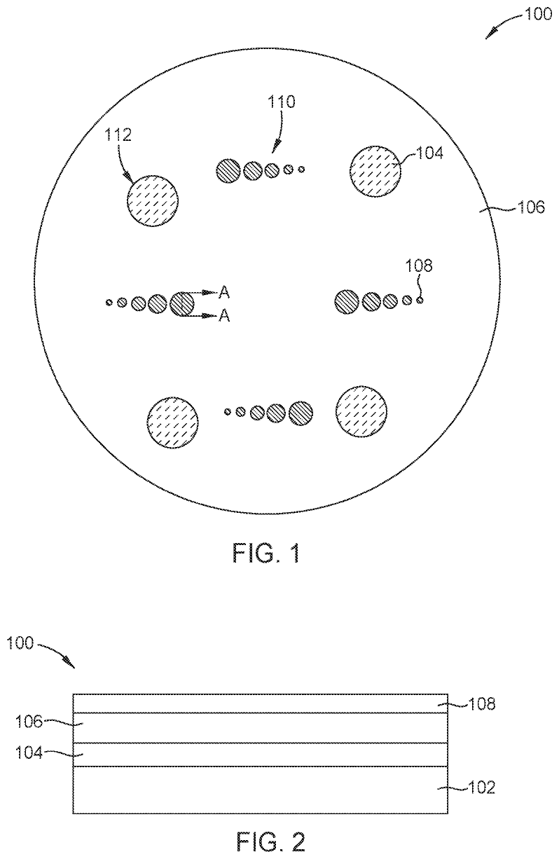

FIG. 1 is a schematic, top view of a piezoelectric device 100. The piezoelectric device 100 shown in FIG. 1 may be partially fabricated and may require other processing steps to form a functional device. The piezoelectric device 100 may be utilized for sensing applications (e.g., gyro-sensors), ultrasound technology, ink-jet printing, or microelectromechanical systems (MEMS) devices, including acoustic resonators for mobile phones and other wireless electronics.

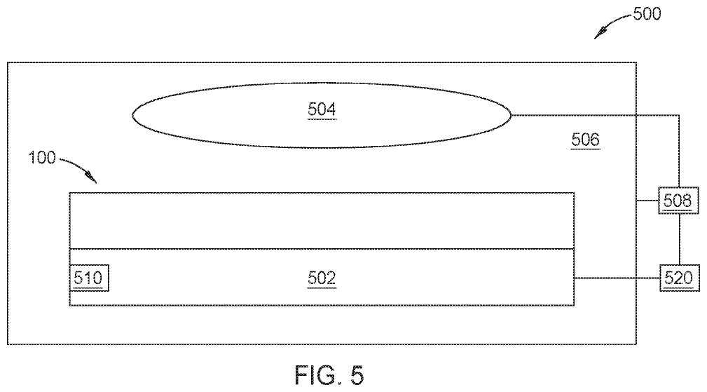

The piezoelectric device 100 includes a substrate 102 (shown in FIGS. 4A-4C), a bottom electrode layer 104, a piezoelectric layer 106, and a top electrode layer 108. In some embodiments, the piezoelectric device 100 may include a high power seed layer disposed between the bottom electrode layer 104 and the piezoelectric layer 106. In another embodiment, the piezoelectric device 100 may include a middle electrode layer, a second high power seed layer, and a second piezoelectric layer. The middle electrode layer is disposed over the piezoelectric layer 106, the second high power seed layer is disposed over the middle electrode layer, and the second piezoelectric layer is disposed between the second high power seed layer and the top electrode layer 108. In another embodiment, additional electrode layers, high power seed layers, and piezoelectric layers may be deposited to achieve the desired thickness and functionality. In yet another embodiment, a primary seed layer may be disposed between the substrate and the bottom electrode layer 104.

The substrate 102 may have a diameter in a range from about 100 mm to about 750 mm and may include silicon (Si), silicon carbide (SIC), SiC-coated graphite, or silicon oxide (SiO₂). In one example, the substrate 102 has a surface area of about 1,000 cm² or more, such as about 2,000 cm² or more, such as about 4,000 cm² or more.

The bottom electrode layer 104 is disposed over a top surface of the substrate 102. The bottom electrode layer 104 is configured to be a bottom electrode for the piezoelectric device 100. Examples of suitable materials for the bottom electrode layer 104 include platinum (Pt), molybdenum (Mo), SrRuO₃, LaNiO₃, CaRuO₃, LaSrMnO₃, and the like. The bottom electrode layer 104 may have a thickness between about 25 nm and about 200 nm, such as between about 50 nm and about 175 nm, such as between about 75 nm and about 150 nm, for example, about 125 nm.

The piezoelectric layer 106 is disposed over the bottom electrode layer 104. In certain embodiments, the piezoelectric layer 106 is formed of one or more layers containing one or more of aluminum nitride (AlN), scandium-doped aluminum nitride (ScAlN), lead zirconate titanate (PZT), lead magnesium niobate-lead titanate (PMN-PT), or lithium niobate (LiNbO₃ or LNO). The piezoelectric layer 106 may have a thickness between about 300 nm and about 2000 nm, such as between about 750 nm and about 1500 nm, such as about 1000 nm. In some embodiments, which can be combined with other embodiments described herein, the thickness of the piezoelectric layer 106 can vary across the surface of the bottom electrode layer 104 between about 300 nm and about 2000 nm. In other embodiments, which can be combined with other embodiments described herein, the thickness of the piezoelectric layer 106 is constant across the surface of the bottom electrode layer 104. The piezoelectric layer 106 is selectively etched via laser etching process to form exposed portions 112 of the bottom electrode layer 104. The exposed portions 112 allow access to the bottom electrode layer 104.

The top electrode layer 108 is disposed over a surface of the piezoelectric layer 106. The top electrode layer 108 is configured to be a top electrode for finished piezoelectric devices. In certain examples, the top electrode layer 108 is formed of the same or different material than the bottom electrode layer 104. Examples of suitable materials for the top electrode layer 108 include platinum (Pt), molybdenum (Mo), SrRuO₃, LaNiO₃, CaRuO₃, LaSrMnO₃, and the like. The top electrode layer 108 may have a thickness between about 25 nm and about 200 nm, such as between about 75 nm and about 150, for example, about 100 nm.

As shown in FIG. 1, the top electrode layer 108 may be patterned as desired on the surface of the piezoelectric layer 106. The top electrode layer 108 is formed with a top electrode pattern 110. The top electrode pattern 110 may be pre-determined prior to fabrication in order to meet the specifications of the piezoelectric device 100. The top electrode pattern 110 of the top electrode layer 108 is not limited to the pattern shown in FIG. 1 and may be adjusted as desired. For example, the top electrode pattern 110 can include circular, rectangular, square, or irregular patterns.

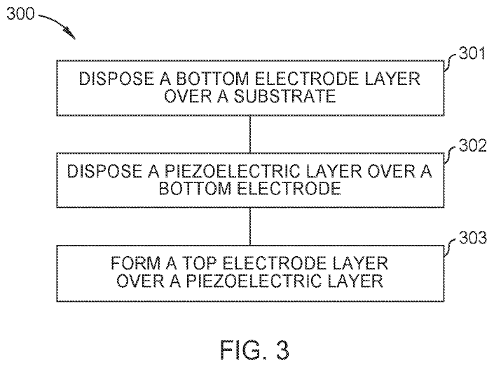

FIG. 2 is a schematic, cross-sectional view of a piezoelectric device 100 at cut line A-A. The bottom electrode layer 104 is disposed over a surface of the substrate 102. The piezoelectric layer 106 is disposed over a surface of the bottom electrode layer 104 along a horizontal plane. The top electrode layer 108 is disposed over a surface of the piezoelectric layer 106. In one embodiment, the bottom electrode layer 104, piezoelectric layer 106, and top electrode layer 108 may be deposited using physical vapor deposition (PVD). In other embodiments, chemical vapor deposition (CVD), atomic layer depositions (ALD), or other suitable deposition processes may be used. The deposition process occurs within a processing chamber configured to perform PVD, CVD, ALD, or other deposition process.

During deposition of the bottom electrode layer 104 and top electrode layer 108, an electrical bias is applied to a pedestal or substrate support within the processing chamber at a static value between about 400 W and about 3000 W. During deposition of the piezoelectric layer 106, a dynamic electrical bias is applied to the pedestal at various power levels between no bias (e.g., 0 W) and about 200 W, such as about 20 W to about 100 W. The pedestal supports the substrate 102 within the chamber.

The variation of the bias (e.g., dynamic bias) results in an average stress within the piezoelectric layer 106 from about 50 MPa to about 300 MPa. The average stress is an average stress of a plurality of stresses along the horizontal plane of the piezoelectric layer 106. The dynamic bias within the piezoelectric layer 106 results in a range of the stress across the substrate 102 between about +/−0 MPa to about +/−100 MPa, e.g. a maximum deviation from the average stress across the substrate is about 100 MPa and a minimum deviation from the average stress across the substrate 102 is about 0 MPa. For example, in one embodiment, the dynamic bias results in an average stress within the piezoelectric layer 106 of about 200 MPa with a range of stress across the substrate 102 between about 100 MPa and about 300 MPa (i.e., +/−100 MPa from the average stress value). In another embodiment, the dynamic bias within the piezoelectric layer 106 is about 100 MPa, with a range of stress across the substrate 102 between about 50 MPa and about 150 MPa (i.e., +/−50 MPa). The dynamic bias can be further adjusted to create average stress values and stress range to conform to the predetermined functionality. Thus, the above examples are not intended to be limiting, as other average stresses and stress ranges are contemplated by this disclosure.

The dynamic bias controls the within-substrate stresses of the piezoelectric layer 106. A controlled stress range means that the piezoelectric layer 106 is flatter (e.g., more planar) within the piezoelectric device 100. The improved planarity affects performance of the piezoelectric device 100 and improves yield in the fabrication of piezoelectric devices 100. Both increasing and decreasing the dynamic bias during formation of the piezoelectric device 100 can affect the stress levels of the piezoelectric layer 106. Large stress ranges within the piezoelectric layer 106 can lead to diminishing performance.

The system can be tuned to a predetermined average stress, and then the dynamic bias is increased or decreased based on the measured value of the stress within the piezoelectric layer 106 to keep the stress level and range close to the predetermined average stress. The dynamic bias can also control the average stress and stress range by controlling the deposition rate and the material properties of the piezoelectric layer 106, such as crystallinity. Increased crystallinity control, for example, allows for the properties of the piezoelectric layer 106 to be more predictable, and thus tuning the dynamic bias to promote the preferred crystalline behavior can facilitate control of the within-substrate stress. Controlling the deposition rate further promotes uniform deposition, assisting in consistent film properties across the piezoelectric layer 106 and resulting in a predetermined average stress and stress range. High volume production (HVP) of these piezoelectric devices 100 is thus enabled.

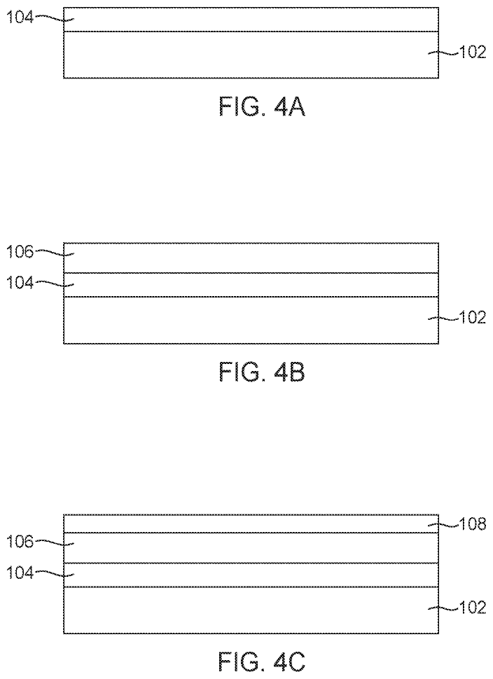

FIG. 3 is a flow diagram of a method 300 of forming a piezoelectric device 100, as shown in FIGS. 4A-4C. FIGS. 4A-4C are schematic, side views of a substrate 102 during the method 300 of forming a piezoelectric device 100.

At operation 301, as shown in FIG. 4A, a bottom electrode layer 104 is disposed over a substrate 102. The substrate 102 is supported on a substrate support or pedestal. The bottom electrode layer 104 may be disposed via a PVD process, a CVD process, or an ALD process, performed in a suitable processing chamber. In certain embodiments, the deposition process is performed between about 25 °C and about 600 °C, such as between about 400 °C and about 600 °C, and such as about 500 °C. In certain embodiments, when depositing via PVD, the pedestal in the processing chamber is negatively biased during the deposition process by a pulsed or continuous power supply providing a DC power to the pedestal with a static electrical bias power level between about 400 W and about 1000 W, such as between about 600 W and about 800 W.

At operation 302, as shown in FIG. 4B, a piezoelectric layer 106 is disposed over the bottom electrode layer 104. The piezoelectric layer 106 is disposed via a PVD process, a CVD process, or an ALD process performed in a suitable processing chamber. In certain embodiments, the target in the processing chamber is negatively biased by a pulsed or continuous power supply providing a RF power to the pedestal. The power supplied to the pedestal is a dynamic bias with power levels between about 0 W and about 200 W, such as about 20 W to about 100 W. During deposition of the piezoelectric layer 106, the power levels are varied to control the stress within the piezoelectric layer 106.

The variation of the bias (e.g., dynamic bias) results in an average stress within the piezoelectric layer 106 from about 50 MPa to about 300 MPa. The dynamic bias is intentionally varied throughout the processing of the substrate in order to achieve a predetermined functionality. The dynamic bias within the piezoelectric layer 106 results in a range of the stress across the substrate 102 between about +/−0 MPa to about +/−200 MPa. In one embodiment, the dynamic bias results in an average stress within the piezoelectric layer 106 of about 200 MPa with a range of stress across the substrate 102 between about 100 MPa and about 300 MPa (i.e., +/−100 MPa from the average stress value). In another embodiment, the dynamic bias within the piezoelectric layer 106 is about 100 MPa, with a range of stress across the substrate 102 between about 50 MPa and about 150 MPa (i.e., +/−50 MPa). The dynamic bias can be further adjusted to create average stress values and stress range to conform to predetermined functionality. Thus, the above examples are not intended to be limiting, as other average stresses and stress ranges are contemplated by this disclosure.

At operation 303, as shown in FIG. 4C, a top electrode layer 108 is formed over the piezoelectric layer 106. The top electrode layer 108 is formed with a top electrode pattern 110. The top electrode layer 108 can be formed at one or more pre-determined locations over the piezoelectric surface 107. In one embodiment, which can be combined with other embodiments described herein, the top electrode layer 108 is deposited on the piezoelectric layer 106 followed by an etch process to form the top electrode pattern 110. The top electrode layer 108 may be is disposed via a PVD process, a CVD process, or an ALD process performed in a suitable processing chamber. In another embodiment, which can be combined with other embodiments described herein, the top electrode layer 108 is sputtered through a proximity mask to form the top electrode pattern 110. Multiple top electrode patterns 110 can be formed over the piezoelectric layer 106. The top electrode pattern 110 is not limited to the patterns shown in FIG. 1.

FIG. 5 is a schematic, cross-sectional view of a processing chamber 500. The processing chamber 500 is utilized in a method for depositing a piezoelectric layer during the fabrication of the piezoelectric device 100.

The processing chamber 500 includes the piezoelectric device 100 disposed on a surface of a stage 502. The stage 502 is disposed in the processing chamber 500 such that the surface of the stage 502 (e.g., pedestal) is positioned opposite a showerhead 504. The processing chamber 500 is operable to deposit the piezoelectric device layers (i.e., top electrode layer 108, piezoelectric layer 106, and bottom electrode layer 104). The process chamber 500 includes a controller 508 and a power source 520. The controller 508 is in communication with the stage 502, the showerhead 504, and the power source 520.

The controller 508 is generally designed to facilitate the control and automation of the methods described herein. The deposition of the piezoelectric device layers (i.e., top electrode layer 108, piezoelectric layer 106, and bottom electrode layer 104) occurs in a process volume 506 of the processing chamber 500. The processing chamber 500 may be a PVD chamber, a CVD chamber, an ALD chamber, or other type of chamber for depositing films. The controller 508 may be coupled to or in communication with a processing chamber 500 and is configured to receive data or input as sensor readings from a plurality of sensors within the processing chamber 500. The controller 508 is further configured to store these sensor readings in a memory.

The sensor readings include any other previous sensor readings from within the processing chamber. The sensor readings include the stored calculated values from after the sensor readings are measured by the controller 508 and run through a system model. The system model is a program configured to estimate the deposition time, thickness, and electrical bias within the processing chamber 500 throughout the deposition process. Therefore, the controller 508 is configured to both retrieve stored sensor readings and save sensor readings for future use. Maintaining previous sensor readings enables the controller 508 to adjust the system model over time to reflect a more accurate version of the processing chamber.

The controller 508 may include and may be in communication with a CPU (i.e., a computer system). The CPU can be a hardware unit or combination of hardware units capable of executing software applications and processing data. The CPU may have a memory and mass storage device, an input control, and a display unit. In some configurations, the CPU includes a digital signal processor (DSP), an application-specific integrated circuit (ASIC), a graphic processing unit (GPU) and/or a combination of such units. The CPU is generally configured to execute the one or more software applications and process stored data. Support circuits are coupled to the CPU for supporting the processor in a conventional manner.

The controller 508 is configured to control the deposition of the top electrode layer 108, the piezoelectric layer 106, and the bottom electrode layer 104, as well as any additional layers that may be deposited over the substrate 102. The controller 508 is further configured to be in communication with a power source 520 to control the electrical bias applied to the stage 502 during the deposition processes. The controller 508 may include a non-transitory computer-readable medium for storing instructions of the deposition process of the piezoelectric device 100. The instructions include, when depositing a bottom electrode layer 104 via PVD as in operation 301 of the method 300, the stage 502 in the processing chamber is negatively biased during the deposition process by a pulsed or continuous power supply (e.g., the power source 520). The power source 520 provides a DC power to the stage 502 with a static electrical bias power level between about 400 W and about 1000 W, such as between about 600 W and about 800 W. The instructions further include, when depositing the piezoelectric layer 106 as in operation 302, varying the electrical bias of the power source 520 applied during deposition of the piezoelectric layer 106. The stage 502 is negatively biased by a pulsed or continuous power supply providing a RF power to the stage 502. The power supplied by the power source 520 to the stage 502 is a dynamic bias with power levels between about 0 W and about 200 W, such as about 20 W to about 100 W.

The stage 502 includes a stage actuator 510. The stage actuator 510 allows the stage 502 to scan in the X direction, the Y direction, and the Z direction, as indicated by the coordinate system shown in FIG. 5. The stage 502 is coupled to the controller 508 in order to provide information of the location of the stage 502 to the controller 508. Additionally, the stage 502 is in communication with the controller 508 such that the stage 502 may move in a direction as desired to etch the piezoelectric layer 106.

In yet another embodiment, which can be combined with other embodiments described herein, the piezoelectric device 100 may undergo further processing to further characterize the piezoelectric device 100.

While the foregoing is directed to embodiments of the present disclosure, other and further embodiments of the disclosure may be devised without departing from the basic scope thereof, and the scope thereof is determined by the claims that follow.

What is claimed is:

1. A method of forming a piezoelectric device, comprising:
disposing a bottom electrode layer over a substrate, the substrate being supported by a pedestal;
disposing a piezoelectric layer over the bottom electrode layer on a horizontal plane;
varying an electrical bias to the pedestal during deposition of the piezoelectric layer; and
forming a top electrode layer with a top electrode pattern over the piezoelectric layer

2. The method of claim 1, wherein the varying of an electrical bias to the pedestal occurs between 0 W and 200 W.

3. The method of claim 1, wherein within the piezoelectric layer an average stress of a plurality of stresses along the horizontal plane is from about 50 MPa to about 300 MPa.

4. The method of claim 3, wherein a maximum deviation from the average stress across the substrate is about 100 MPa and a minimum deviation from the average stress across the substrate is about 0 MPa.

5. The method of claim 1, further comprising applying a static electrical bias to the pedestal during deposition of the bottom electrode layer and the top electrode layer of between 400 W and 3000 W.

6. The method of claim 1, wherein the piezoelectric layer includes one or more of aluminum nitride (AlN), scandium-doped aluminum nitride (ScAlN), lead zirconate titanate (PZT), lead magnesium niobate-lead titanate (PMN-PT), or LiNbO₃ (LNO).

7. The method of claim 1, wherein the bottom electrode layer, piezoelectric layer, and top electrode layer are disposed using physical vapor deposition (PVD), chemical vapor deposition (CVD), or atomic layer deposition (ALD).

8. The method of claim 1, wherein the top electrode layer and the bottom electrode layer include platinum (Pt), molybdenum (Mo), SrRuO₃, LaNiO₃, CaRuO₃, or LaSrMnO₃.

9. A piezoelectric device, comprising:
a substrate;
a bottom electrode layer formed over the substrate;
a piezoelectric layer formed over the bottom electrode layer on a horizontal plane, wherein within the piezoelectric layer an average stress of a plurality of stresses along the horizontal plane is about 50 MPa to about 300 MPa; and
a top electrode layer formed on the piezoelectric layer.

10. The piezoelectric device of claim 9, wherein the piezoelectric layer includes one or more of aluminum nitride (AlN), scandium-doped aluminum nitride (ScAlN), lead zirconate titanate (PZT), lead magnesium niobate-lead titanate (PMN-PT), or LiNbO₃ (LNO).

11. The piezoelectric device of claim 9, wherein the piezoelectric layer has a thickness between 300 nm and 2000 nm.

12. The piezoelectric device of claim 9, wherein a thickness of the piezoelectric layer varies across a surface of the bottom electrode layer between 300 nm and 2000 nm.

13. The piezoelectric device of claim 9, wherein the top electrode layer and the bottom electrode layer include platinum (Pt), molybdenum (Mo), SrRuO₃, LaNiO₃, CaRuO₃, or LaSrMnO_{3.}

14. The piezoelectric device of claim 9, wherein the bottom electrode layer has a thickness between 25 nm and 200 nm.

15. The piezoelectric device of claim 9, wherein the top electrode layer has a thickness between 25 nm and 200 nm.

16. A controller of a process system storing instructions that, when executed by a processor, causes the system to:
process a substrate within a processing chamber by disposing a bottom electrode layer over a substrate, the substrate being supported by a pedestal;
dispose a piezoelectric layer over the bottom electrode layer along a horizontal plane;
vary an electrical bias to the pedestal during deposition of the piezoelectric layer; and
form a top electrode layer with a top electrode pattern over the piezoelectric layer.

17. The controller of claim 16, wherein the electrical bias to the pedestal is varied between 0 W and 200 W.

18. The controller of claim 16, wherein within the piezoelectric layer an average stress of a plurality of stresses along the horizontal plane is from about 50 MPa to about 300 MPa.

19. The controller of claim 18, wherein a maximum deviation from the average stress across the substrate is about 100 MPa and a minimum deviation from the average stress across the substrate is about 0 MPa.

20. The controller of claim 16, wherein the piezoelectric layer includes one or more of aluminum nitride (AlN), scandium-doped aluminum nitride (ScAlN), lead zirconate titanate (PZT), lead magnesium niobate-lead titanate (PMN-PT), or LiNbO₃ (LNO).
